(19) United States
(12) Patent Application Publication
(10) Pub. No.: US 2025/0201720 A1
(43) Pub. Date: Jun. 19, 2025

(54) METHODS, SYSTEMS, APPARATUS, AND ARTICLES OF MANUFACTURE TO REDUCE INTERMETALLIC COMPOUND FORMATION IN INTEGRATED CIRCUIT PACKAGES

(71) Applicant: Intel Corporation, Santa Clara, CA (US)

(72) Inventors: Minglu Liu, Chandler, AZ (US); Farzaneh Saeedifard, Chandler, AZ (US); Ali Lehaf, Phoenix, AZ (US); Steve Sungyeol Cho, Chandler, AZ (US); Srinivas Venkata Ramanuja Pietambaram, Chandler, AZ (US); Liang He, Chandler, AZ (US); Jung Kyu Han, Chandler, AZ (US); Gang Duan, Chandler, AZ (US); Yosuke Kanaoka, Chandler, AZ (US); Andrey Gunawan, Scottsdale, AZ (US); Yingying Zhang, Chandler, AZ (US)

(21) Appl. No.: 18/540,217

(22) Filed: Dec. 14, 2023

(51) Int. Cl. H01L 23/538; H01L 21/48; H01L 23/00

(52) U.S. Cl. CPC H01L 23/5381; H01L 21/4857; H01L 23/5383; H01L 24/05; H01L 24/13; H01L 24/16; H01L 24/81; H01L 2224/05647; H01L 2224/13109; H01L 2224/13139; H01L 2224/13147; H01L 2224/13655; H01L 2224/13657; H01L 2224/1366; H01L 2224/1369; H01L 2224/16227; H01L 2224/81801

(57) ABSTRACT

Methods, systems, apparatus, and articles of manufacture to reduce intermetallic compound formation in integrated circuit packages are disclosed. An example package substrate includes a buildup layer including a metal pad, an interconnect bridge embedded in the buildup layer, the interconnect bridge including a first contact pad on a first side of the interconnect bridge and a second contact pad on a second side of the interconnect bridge, the second side opposite the first side, and solder positioned between the metal pad and the first contact pad, the solder to electrically couple the metal pad and the first contact pad, a weight percent of nickel in any layer of material between the metal pad and the first contact pad being less than a threshold.

### FIELD OF THE DISCLOSURE

This disclosure relates generally to integrated circuit packages and, more particularly, to methods, systems, apparatus, and articles of manufacture to reduce intermetallic compound formation in integrated circuit packages.

### BACKGROUND

In many integrated circuit packages, one or more semiconductor dies can be mechanically and electrically coupled to an underlying package substrate. In some instances, the underlying package substrate can include a semiconductor based interconnect bridge embedded therein.

### BRIEF DESCRIPTION OF THE DRAWINGS

FIG. 1 illustrates an example integrated circuit (IC) package on a printed circuit board (PCB).

FIG. 2 is a cross-sectional view of a portion of an example package substrate that may be included in the example IC package of FIG. 1.

FIG. 3 is a cross-sectional view of an example contact pad that may be included in the example package substrate of FIG. 2.

FIG. 4 illustrates an example organic barrier material provided on a surface of the example contact pad of FIG. 3.

FIG. 5 illustrates an example organic diffusion barrier layer produced after applying heat to the organic barrier material of FIG. 4.

FIG. 6 illustrates example solder provided on the example organic diffusion barrier layer of FIG. 5.

FIG. 7A illustrates a first example solder joint including first example metallic diffusion barrier layers implemented between example solder and respective example contact pads.

FIG. 7B illustrates a second example solder joint including second example metallic diffusion barrier layers implemented between example solder and respective example contact pads.

FIG. 8A illustrates a third example solder joint including second example solder material implemented between example contact pads.

FIG. 8B illustrates a fourth example solder joint including third example solder material implemented between example contact pads.

FIG. 9 is a flowchart representative of an example method of manufacturing the example package substrate of FIGS. 1 and/or 2 including the example organic diffusion barrier layer of FIGS. 5 and/or 6.

FIG. 10 is a flowchart representative of an example method of manufacturing the example package substrate of FIGS. 1 and/or 2 including one or more of the example metallic diffusion barrier layers of FIGS. 7A and/or 7B and/or the example solder of FIGS. 8A and/or 8B.

FIG. 11 is a top view of a wafer including dies that may be included in an IC package constructed in accordance with teachings disclosed herein.

FIG. 12 is a cross-sectional side view of an IC device that may be included in an IC package constructed in accordance with teachings disclosed herein.

FIG. 13 is a cross-sectional side view of an IC device assembly that may include an IC package constructed in accordance with teachings disclosed herein.

FIG. 14 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Interconnect bridges can be used to connect dies coupled to a package substrate. Such interconnect bridges are disposed within cavities of the package substrate and provide features that enable electrical coupling of the dies thereto. Some interconnect bridges include and/or correspond to semiconductor dies that include compute components, where such compute components can increase the processing density of integrated circuits including the interconnect bridges. In some examples, the compute components within interconnect bridges are passive and do not include active semiconductor devices (e.g., transistors). For instance, an interconnect bridge can contain electrical routing (e.g., traces, connecting vias, etc.) without any active components. In some examples, an interconnect bridge may include at least some active components.

While interconnect bridges can increase the processing density of integrated circuits, such increased processing density offered by the interconnect bridges may also increase power consumption. To compensate for such increased power consumption, some interconnect bridges can be connected to a power source of an integrated circuit (IC) package by one or more vias (e.g., through silicon vias (TSVs)) extending through the package substrate. For instance, first contact pads (e.g., first metal pads) on an exterior surface of the interconnect bridges can be soldered to second contact pads (e.g., second metal pads) coupled to the vias to mechanically and/or electrically couple the interconnect bridges to the package substrate. In some instances, the first and second contact pads include a first metallic material (e.g., copper), and the solder includes a second metallic material (e.g., tin) different from the first metallic material.

In some instances, electromigration (e.g., diffusion) may occur between the solder and at least one of the contact pads. As used herein, electromigration refers to the transport of metal ions caused by current flow between two or more metallic materials. For instance, when current flows through the solder between the first and second contact pads, the resulting electromigration may produce material defects in and/or between the solder and the first and second contact pads. In particular, electromigration may produce cracks and/or hillocks in the solder and/or the contact pads, and/or may result in intermetallic compound (IMC) formation at an interface between the solder and at least one of the contact pads. Such material defects can reduce mechanical and/or electrical reliability of the solder joints and, in some examples, can reduce a threshold amount of current (e.g., a maximum current (Imax)) that can flow through the solder joints. As advancements in technology enable reduction in size and/or increases in interconnect density of integrated circuit packages, reducing an amount (e.g., a thickness) of IMC formed at the solder joints can improve electrical performance and/or efficiency of the IC package.

Examples disclosed herein can reduce IMC formation and/or other material defects caused by electromigration between two or more metallic materials at an example solder joint of an example integrated circuit (IC) package. In examples disclosed herein, an example diffusion barrier layer is positioned between an example contact pad (e.g., a metal pad, a copper pad) and example solder of the IC package, where the diffusion barrier layer can inhibit electromigration and/or diffusion of material between the contact pad and the solder. In some examples, the contact pad corresponds to a first contact pad included in an example buildup layer of an example package substrate of the IC package. In some examples, the contact pad corresponds to a second contact pad on a first side of an example interconnect bridge embedded in the buildup layer. In some examples, the contact pad corresponds to a third contact pad on a second side of the interconnect bridge opposite the first side, and/or a fourth contact pad on an inner (e.g., facing) surface of the package substrate and/or a semiconductor die. In some examples, the diffusion barrier layer includes an example organic barrier material (e.g., an organic thermal cross-linked material) including at least one of a thermal cross-linker or a photo cross-linker. In some examples, the organic barrier material includes at least one of benzimidazole or a carboxylic acid. Additionally or alternatively, the diffusion barrier layer can include one or more example alloys (e.g., metallic alloys) including nickel, iron, and/or cobalt.

In some examples, in addition to or instead of providing the diffusion barrier layer, examples disclosed herein can include two or more example metals in the solder to inhibit IMC formation between the solder and the contact pad. For example, the solder can include an example metallic alloy including at least tin and indium. In some examples, the metallic alloy can include copper. In some examples, by utilizing solder that includes the metallic alloy, examples disclosed herein can more effectively inhibit electromigration compared to when a single metal (e.g., tin) is used for the solder. Advantageously, by utilizing at least one of the diffusion barrier layer or the alloyed solder material to inhibit IMC formation, examples disclosed herein may improve mechanical and/or electrical reliability of solder joints in an IC package.

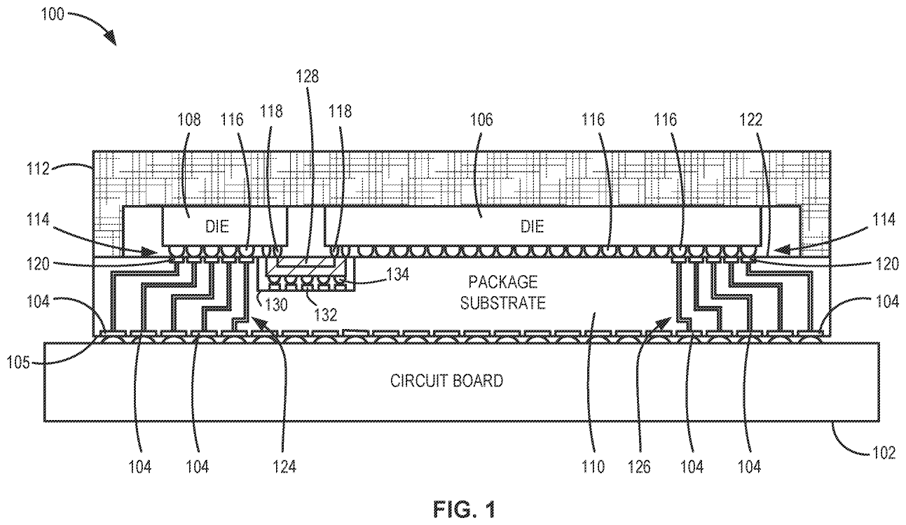

FIG. 1 illustrates an example IC package (e.g., a semiconductor package) 100 constructed in accordance with teachings disclosed herein. In the illustrated example, the IC package 100 is conductively (e.g., electrically) coupled to an example circuit board 102 via an array of example contact pads or lands 104 on an example mounting surface (e.g., a bottom surface) 105 of the package. In some examples, the IC package 100 may include balls, pins, and/or pads, in addition to or instead of the contact pads 104, to enable the conductive coupling of the package 100 to the circuit board 102. In this example, the package 100 includes first and second example dies (e.g., silicon dies, semiconductor dies) 106, 108 (sometimes also referred to as chips or chiplets) that are mounted to an example package substrate 110 and enclosed by an example package lid or mold compound 112. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is conductively and mechanically coupled to the substrate 110 via corresponding arrays of example interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, example core bumps 116 and example bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and conductively coupled to contact pads 120 on an example inner surface 122 of the substrate 110. The contact pads 120 on the inner surface 122 of the package substrate 110 are conductively coupled to the contact pads 104 on the bottom (external) surface 105 of the substrate 110 (e.g., a surface opposite the inner surface 122) via example internal interconnects 124, 126 within the substrate 110. As a result, there is a complete signal path between the bumps 116 of the dies 106, 108 and the contact pads 104 mounted to the circuit board 102 that pass through the contact pads 120 and the interconnects 124, 126 provided therebetween.

As used herein, bridge bumps are bumps on the dies 106, 108 through which electrical signals pass between different ones of the dies within an IC package. More particularly, bridge bumps differ from core bumps in that bridge bumps electrically connect two or more different dies via an interconnect bridge (e.g., an example interconnect bridge 128 of FIG. 1) embedded in an underlying substrate (e.g., the package substrate 110). In some examples, the interconnect bridge 128 is fabricated from a semiconductor wafer in a manner similar to the dies 106, 108. Thus, the interconnect bridge 128 is also sometimes referred to herein as a semiconductor die or a semiconductor based interconnect bridge. As represented in FIG. 1, core bumps 116 are typically larger than bridge bumps 118. In this example, the interconnect bridge 128 is positioned within an example cavity 130 in the inner surface 122 of the package substrate 110. In the past, interconnect bridges typically included contacts pads on the surface facing away from the package substrate 110 and toward the dies 106, 108 (e.g., to provide conductive coupling between the dies 106, 108). However, in this example, the example interconnect bridge 128 is conductively and mechanically coupled to the package substrate 110 via first example contact pads 132 (on the package substrate 110) and second example contact pads 134 (on the interconnect bridge 128). Therefore, the dies 106, 108 may be conductively coupled to one another and to the package substrate 110 via the bridge bumps 118, the interconnect bridge 128, and the contact pads 132, 134.

In some examples, mechanically coupling (e.g., embedding) the interconnect bridge 128 to the package substrate 110 is accomplished by soldering the first and second contact pads 132, 134 together such that electrical signals can pass between the interconnect bridge 128 and the package substrate 110. In particular, the second contact pads 134 on the interconnect bridge 128 are soldered to the first contact pads 132 on the package substrate 110. In such examples, the package substrate 110 includes additional internal interconnects 124, 126 conductively coupled to the first contact pads 132 to provide a signal path through the package substrate 110. In some examples, the first and second contact pads 132, 134 include a first metallic material (e.g., copper), and the solder therebetween includes a second metallic material (e.g., tin) different from the first metallic material.

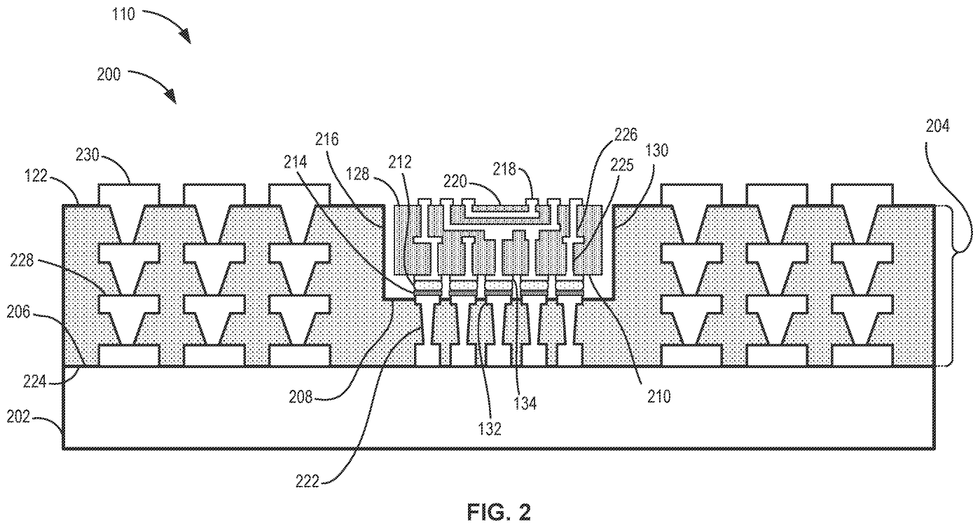

FIG. 2 illustrates a cross-sectional view of an example portion 200 of the example package substrate 110 of FIG. 1. It should be appreciated that the portion 200 and one or more components disposed therein are not to scale and can have other proportions, shapes, quantities, and/or relative sizes. In some examples, the portion 200 can include additional components and/or layers (not illustrated).

In the illustrated example of FIG. 2, the portion 200 of the package substrate 110 corresponds to layers of the package substrate 110 from an example core (e.g., glass core, organic core, etc.) 202 of the package substrate 110 to the inner surface 122 of the package substrate 110. In some examples, the core 202 includes at least one of: aluminosilicate, borosilicate, alumino-borosilicate, silica, and/or fused silica. In some examples, the core 202 includes one or more additives including: aluminum oxide (Al2O3), boron trioxide (B2O3), magnesia oxide (MgO), calcium oxide (CaO), stoichiometric silicon oxide (SrO), barium oxide (BaO), stannic oxide (SnO2), nickel alloy (Na2O), potassium oxide (K2O), phosphorus trioxide (P2O3), zirconium dioxide (ZrO2), lithium oxide (Li2O), titanium (Ti), and/or zinc (Zn). In some examples, the core 202 includes silicon and oxygen. In some examples, the core 202 includes silicon, oxygen and/or one or more of aluminum, boron, magnesium, calcium, barium, tin, sodium, potassium, strontium, phosphorus, zirconium, lithium, titanium, and/or zinc. In some examples, the core 202 includes at least 23 percent silicon by weight and at least 26 percent oxygen by weight. In some examples, the glass core is a layer of glass including silicon, oxygen and aluminum. In some examples, the core 202 includes at least 23 percent silicon by weight, at least 26 percent oxygen by weight, and at least 5 percent aluminum by weight. In some examples, the core 202 is an amorphous solid glass layer. In some examples, the core 202 is a layer of glass that does not include an organic adhesive or an organic material. In some examples, the core 202 is a solid layer of glass having a rectangular shape in plan view. In some examples, the core 202, as a glass substrate, includes at least one glass layer and does not include epoxy and does not include glass fibers (e.g., does not include an epoxy-based prepreg layer with glass cloth). In some examples, the core 202 corresponds to a single piece of glass that extends the full height/thickness of the core. In other examples, the core 202 can be silicon, a dielectric material and/or any other material(s). In some examples, the core 202 has a rectangular shape that is substantially coextensive, in plan view, with the layers above and/or below the core. In some examples, the core 202 has a thickness in a range of about 50 micrometers (μm) to about 1.4 millimeters (mm). In some examples, the core 202 can be a multi-layer glass substrate (e.g., a coreless substrate), where a glass layer has a thickness in a range of about 25 μm to about 50 μm. In some examples, the core 202 can have dimensions of about 10 mm on a side to about 250 mm on a side (e.g., 10 mm by 10 mm to 250 mm by 250 mm). In some examples, the core 202 corresponds to a rectangular prism volume with section (e.g., vias) removed and filled with other materials (e.g., metal).

The portion 200 of the example package substrate 110 shown in FIG. 2 includes an example buildup layer (e.g., a buildup region) 204 on an example surface 206 of the core 202. The buildup layer 204 is an insulative layer of the package substrate 110 that can be used to support and/or house other components of the package substrate 110. In some examples, the buildup layer 204 can be composed of any suitable nonconductive (e.g., dielectric) material, such as glass, resin, or buildup film. Although the buildup layer 204 is represented in FIG. 2 as a single, unitary layer of material, in some examples, the buildup layer 204 may include multiple layers of laminated dielectric material. In some such examples, the package substrate 110 may include one or more conductive layers between adjacent ones of the dielectric layers.

In the illustrated example of FIG. 2, the buildup layer 204 includes the cavity 130, and the interconnect bridge 128 is disposed in the cavity 130. In this example, the package substrate 110 includes a space (e.g., a gap) between example walls 216 of the cavity 130 and the interconnect bridge 128. In some examples, the interconnect bridge 128 may be spaced 40 μm or less, 50 μm or less, 60 μm or less, etc., from the walls 216 of the cavity 130. In some examples, the buildup layer 204 can be filled in between the walls 216 and the interconnect bridge 128. In some examples, the interconnect bridge 128 constitutes and/or can be implemented as an example semiconductor die (e.g., similar to the first die 106, the second die 108, etc. of FIG. 1). However, in some examples, the semiconductor die that serves as the interconnect bridge 128 does not include any active semiconductor devices (e.g., does not include transistors). In other examples, the semiconductor die that serves as the interconnect bridge 128 includes active semiconductor devices.

In the illustrated example of FIG. 2, the example interconnect bridge 128 is electrically and mechanically coupled to the package substrate 110. In particular, the first contact pads (e.g., first metal pads) 132 positioned in the cavity 130 are coupled to the second contact pads (e.g., second metal pads) 134 positioned on the interconnect bridge 128. The first contact pads 132 are positioned on a first example surface 208 of the package substrate 110, and the second example contact pads 134 are positioned on a first example surface 210 of the interconnect bridge 128, where the first surface 208 faces the second surface 210. In this example, the first example surface 208 is recessed relative to the inner surface 122 of the package substrate 110 (defining the cavity 130).

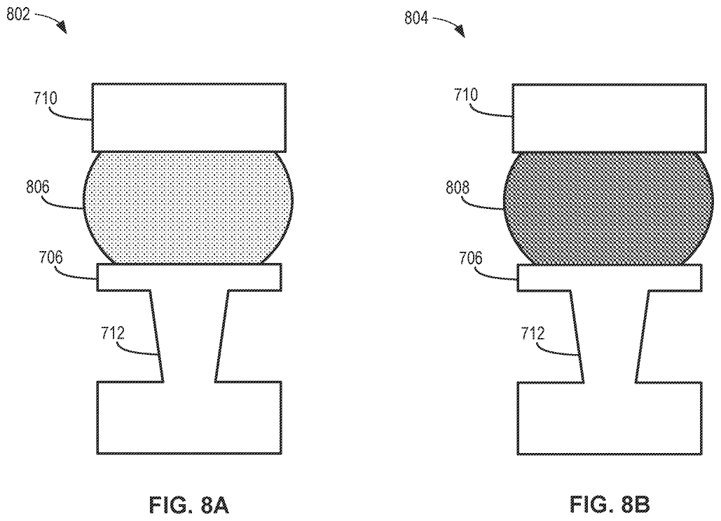

In the illustrated example of FIG. 2, the package substrate 110 is mechanically coupled (e.g., attached) to the interconnect bridge 128 via one or more solder joint connections. For example, example solder (e.g., solder material) 212 is positioned between corresponding ones of the first and second contact pads 132, 134 to electrically and/or mechanically couple the interconnect bridge 128 to the package substrate 110. In some examples, thermocompression bonding is used to couple the first and second contact pads 132, 134 at the solder 212. In some examples, the solder 212 includes tin. In some examples, the solder 212 can include one or more additional materials (e.g., metals) as described below in connection with FIGS. 8A and/or 8B.

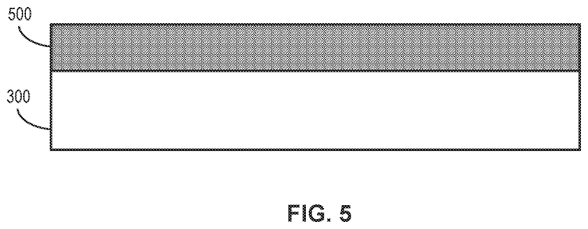

In some examples, during operation of an electronic device implementing the package substrate 110 of FIG. 2, current may flow through the solder 212 and between corresponding ones of the first and second contact pads 132, 134. In some examples, the flow of current produces an electric field that may result in electromigration (e.g., diffusion) of material between the contact pads 132, 134 and the solder 212. Such electromigration may result in material defects and/or promote IMC formation at an interface between the solder 212 and the contact pads 132, 134, thereby reducing reliability of the IC package 100. In the illustrated example of FIG. 2, an example diffusion barrier layer 214 is positioned (e.g., disposed) between the solder 212 and corresponding one(s) of the first contact pads 132. In some examples, the diffusion barrier layer 214 can reduce diffusion of material caused by electromigration and, thus, can inhibit IMC formation at the interface between the solder 212 and the corresponding one(s) of the first contact pads 132. In some examples, the diffusion barrier layer 214 can be positioned between the solder 212 and the second contact pads 134 (e.g., in addition to or instead of being positioned between the solder 212 and the first contact pads 132). Different example implementations of the diffusion barrier layer 214 are described below in connection with FIGS. 5, 6, 7A, and/or 7B.

In the illustrated example of FIG. 2, the interconnect bridge 128 can include third example contact pads 218 positioned on a third example surface 220 of the interconnect bridge 128, where the third surface 220 (e.g., the die-side surface) is opposite the second surface 210 (e.g., the package substrate side surface) of the interconnect bridge 128. In some examples, one(s) of the third contact pads 218 are couplable to one or more additional semiconductor dies. For example, the one(s) of the third contact pads 218 can be coupled to the first die 106 of FIG. 1 and/or the second die 108 of FIG. 1. In some examples, a first one of the third contact pads 218 can couple to the first die 106 and a second one of the third contact pads 218 can couple to the second die 108. In some such examples, the first and second ones of the third contact pads 218 are conductively coupled through conductive routing within the interconnect bridge 128. Accordingly, the first die 106 can be conductively coupled to the second die 108 through the third contact pads 218. In some examples, the first and second dies 106, 108 can include contact pads that can conductively couple to the third contact pads 218. For example, the bridge bumps 118 of FIG. 1 can conductively couple to the third contact pads 218 to facilitate electrical connection between the dies 106, 108 and the interconnect bridge 128. The example interconnect bridge 128 can be implemented as an embedded multi-die interconnect bridge (EMIB). In some examples, the diffusion barrier layer 214 can be positioned on one or more of the third contact pads 218 (e.g., in addition to or instead of being positioned between the solder 212 and at least one of the first contact pads 132 or the second contact pads 134).

In some examples, the example interconnect bridge 128 can conductively couple to first example vias 222. As shown in FIG. 2, the first vias 222 extend through the buildup layer 204 from the first contact pads 132 toward a fourth example surface 224 of the buildup layer 204, the fourth example surface 224 facing away from the first surface 208. In this example, the first vias 222 and the interconnect bridge 128 are conductively coupled through the first and second contact pads 132, 134. In some examples, the first vias 222 are referred to as through silicon vias (TSVs). In some examples, the second contact pads 134 are electrically coupled to the third contact pads 218 through third example vias (e.g., through silicon vias (TSVs)) 225 and example routing (e.g., traces) 226 extending through the interconnect bridge 128.

In the illustrated example of FIG. 2, the package substrate 110 includes second example vias 228 extending between the fourth surface 224 of the buildup layer 204 and the inner surface 122 of the package substrate 110. In this example, the second vias 228 serve as and/or correspond to ones of the internal interconnects 124, 126 that extend through the package substrate 110 as shown in FIG. 1. In the example of FIG. 2, the second vias 228 are coupled to fourth example contact pads 230 on the inner surface 122 of the package substrate 110, where the fourth contact pads 230 can serve as and/or correspond to ones of the contact pads 120 of FIG. 1. In some examples, the diffusion barrier layer 214 can be positioned on one(s) of the fourth contact pads 230 to inhibit IMC formation between the fourth contact pads 230 and the core bumps 116 of FIG. 1. Additionally or alternatively, the diffusion barrier layer 214 can be positioned on one(s) of the contact pads 104 of FIG. 1.

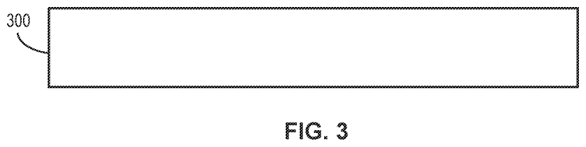

FIG. 3 is a cross-sectional view of an example contact pad (e.g., a metal pad) 300 that may be included in the example package substrate 110 of FIGS. 1 and/or 2. In some examples, the contact pad 300 corresponds to one of the first contact pads 132, the second contact pads 134, the third contact pads 218, or the fourth contact pads 230 of FIG. 2. In some examples, the contact pad 300 is fabricated from a first metallic material (e.g., copper). The contact pad 300 is produced as a single layer. In some examples, the contact pad 300 can include two or more layers coupled together to produce the contact pad 300.

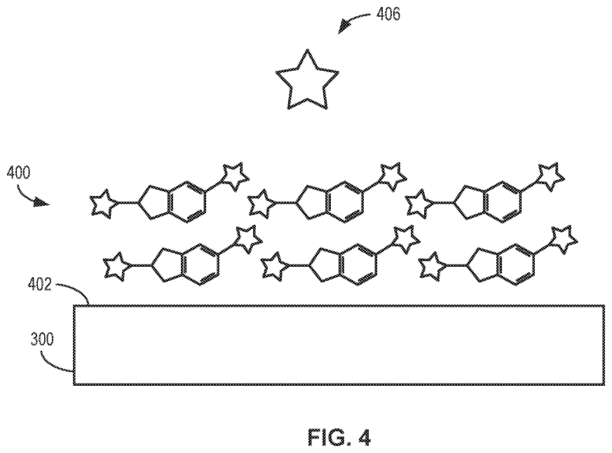

FIG. 4 illustrates an example organic barrier material 400 provided on an example surface 402 of the example contact pad 300 of FIG. 3. In the illustrated example of FIG. 4, the organic barrier material 400 includes one or more example thermal cross-linkers (e.g., thermal cross-linking material(s)) and/or one or more example photo cross-linker (e.g., a photo cross-linking material). In particular, the thermal cross-linkers promote bonding of two or more molecules under exposure to heat, and the photo cross-linkers promote bonding of two or more molecules under exposure to light. In some examples, the thermal cross-linkers and/or the photo cross-linkers include at least carbon and hydrogen. In some examples, the thermal cross-linkers and/or the photo cross-linkers can include one or more benzocyclobutenes, styrenes, acrylates, and/or cinnamates. In some examples, the organic barrier material 400 further includes at least one example substituent material (e.g., represented by an example molecule 406). In some examples, the substituent material includes at least one of benzimidazole or a carboxylic acid. In particular, the carboxyl functional group (COOH) material includes a carbon (C) atom bonded to an oxygen (O) atom by a double bond and bonded to a hydroxyl group (—OH) by a single bond. In some examples, one or more different substituent materials can be used instead. In some examples, the organic barrier material 400 is provided (e.g., deposited) in one or more layers to coat the surface 402 of the contact pad 300. In some examples, the organic barrier material 400 is provided on the surface 402 using an organic solderability preservative (OSP) method for coating.

FIG. 5 illustrates an example organic diffusion barrier layer (e.g., a cross-linked organic diffusion barrier layer) 500 produced after applying heat and/or light to the organic barrier material 400 of FIG. 4. For example, heat and/or light is applied to the organic barrier material 400 to promote thermal cross-linking and/or photo cross-linking of the organic barrier material 400. As used herein, cross-linking refers to a process of chemically joining two or more molecules by a covalent bond. In this example, as a result of applying the heat and/or light to the organic barrier material 400, the cross-linker (e.g., thermal cross-linker and/or photo cross-linker) molecules and the at least one substituent material in the organic barrier material 400 are bonded together to produce the organic diffusion barrier layer 500 with cross-linking. In some examples, the organic diffusion barrier layer 500 is between 100 nanometers (nm) and 200 nm. In some examples, the organic diffusion barrier layer 500 can have a different thickness. In some examples, the organic diffusion barrier layer 500 can be used for the diffusion barrier layer 214 described above in connection with FIG. 2.

In some examples, to produce the organic diffusion barrier layer 500 with cross-linking, a temperature of the heat applied to the organic barrier material 400 is between 200 degrees Celsius and 300 degrees Celsius. In some examples, a threshold temperature at which thermal cross-linking occurs can be varied based on the type(s) and/or the amount(s) of the substituent material(s) included in the organic barrier material 400. For example, the threshold temperature can be reduced by increasing an amount (e.g., a weight percent) of the substituent material(s) in the organic barrier material 400. Conversely, in some examples, the threshold temperature can be increased by reducing the amount of the substituent material(s) in the organic barrier material 400.

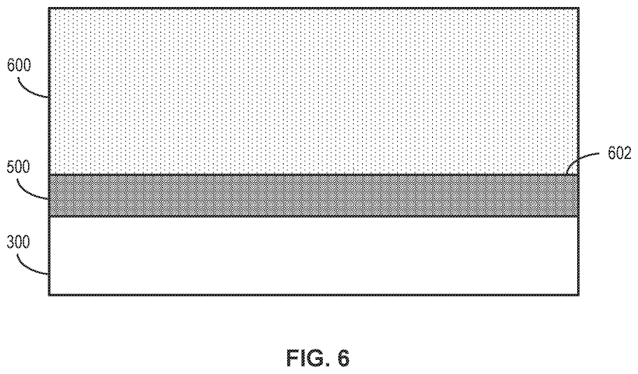

FIG. 6 illustrates example solder 600 provided on the example organic diffusion barrier layer 500 of FIG. 5. For example, the solder 600 can be provided on an example surface 602 of the organic diffusion barrier layer 500 to electrically couple the contact pad 300 to one or more components (e.g., the dies 106, 108, the interconnect bridge 128, the package substrate 110, etc.) of the IC package 100 of FIG. 1. In some examples, the solder 600 includes tin and/or silver. In some examples, the solder 600 can include one or more different materials (e.g., in addition to or instead of tin and/or silver) as described below in connection with FIGS. 8A and/or 8B.

In some examples, as a result of the additional bonds (e.g., cross-links, polymer matrices) created during heating of the organic barrier material 400 of FIG. 4, the organic diffusion barrier layer 500 can more effectively inhibit (e.g., block, reduce) diffusion of material between the contact pad 300 and the solder 600 (e.g., compared to the organic barrier material 400 prior to heating). In some examples, when the organic diffusion barrier layer 500 includes a carboxyl functional group (COOH) material, electrostatic interaction between the COOH material and the contact pad 300 can further suppress (e.g., inhibit) electromigration of atoms (e.g., copper atoms) from the contact pad 300. In some examples, in addition to inhibiting diffusion and/or electromigration between the contact pad 300 and the solder 600, the organic diffusion barrier layer 500 can be used to inhibit (e.g., suppress) oxidation of metal (e.g., copper) in the contact pad 300.

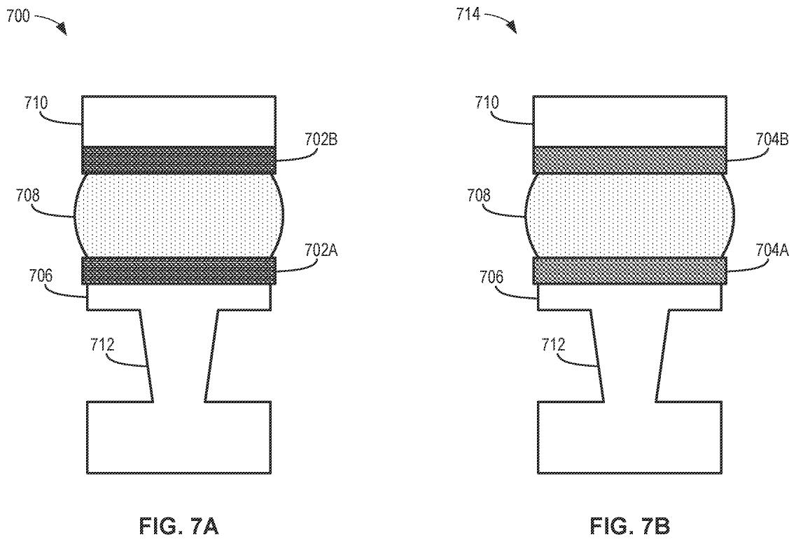

FIGS. 7A and 7B illustrate first and second example metallic diffusion barrier layers 702, 704, respectively, that can be implemented in the example IC package 100 of FIG. 1. In particular one or both of the first metallic diffusion barrier layer 702 or the second metallic diffusion barrier layer 704 may be included in the IC package 100 in some examples. In the illustrated example of FIG. 7A, a first example solder joint (e.g., a first interconnect joint) 700 includes a first one of the first metallic diffusion barrier layers 702A coupled between a first contact pad (e.g., a first metal pad) 706 and example solder 708, and a second one of the first metallic diffusion barrier layers 702B coupled between the solder 708 and a second contact pad (e.g., a second metal pad) 710. In some examples, one of the first metallic diffusion barrier layers 702 (e.g., the first one of the first metallic diffusion barrier layers 702A or the second one of the first metallic diffusion barrier layers 702B) may be omitted. In the example of FIG. 7A, the first contact pad 706 is electrically and/or mechanically coupled to an example via 712. In some examples, the first contact pad 706 corresponds to one of the first contact pads 132, the via 712 corresponds to one of the vias 222, and the second contact pad 710 corresponds to one of the second contact pads 132 of FIGS. 1 and/or 2. In some examples, the first metallic diffusion barrier layer 702 is used for the diffusion barrier layer 214 of FIG. 2 (e.g., in addition to or instead of the organic diffusion barrier layer 500 of FIGS. 5 and/or 6).

In the illustrated example of FIG. 7A, the first contact pad 706, the second contact pad 710, and the via 712 include copper, and the solder 708 includes tin. In some examples, in addition to tin, the solder 708 includes trace amounts (e.g., 0.1 weight percent or above) of one or more additional materials (e.g., nickel, silver, germanium, etc.). Further, the first metallic diffusion barrier layer(s) 702 include a first example alloy (e.g., a nickel-iron (NiFe) alloy) including nickel (Ni) and iron (Fe). In some examples, the first alloy can include less than a threshold amount of nickel. For example, the first alloy can include less than 90 weight percent of nickel, less than 80 weight percent of nickel, less than 70 weight percent of nickel, less than 60 weight percent of nickel, less than 50 weight percent of nickel, less than 40 weight percent of nickel, less than 30 weight percent of nickel, less than 20 weight percent of nickel, less than 10 weight percent of nickel, etc. In some examples, the first metallic diffusion barrier layer(s) 702 can be provided on a surface of at least one of the first contact pad 706, the second contact pad 710, or the solder 708 using at least one of an electrolytic plating technique or an electroless plating technique. For example, nickel and iron can be combined to produce the nickel-iron alloy, and the nickel-iron alloy is provided (e.g., deposited) on the at least one of the first contact pad 706, the second contact pad 710, or the solder 708. In some examples, alternating layers of nickel and iron are provided on the at least one of the first contact pad 706, the second contact pad 710, or the solder 708, and heat and/or pressure is applied to the layers of nickel and iron to produce the nickel-iron alloy. In some examples, thermocompression bonding can be used to couple (e.g., join, combine) together the first contact pad 706, the first one of the first metallic diffusion barrier layers 702A, the solder 708, the second one of the first metallic diffusion barrier layers 702B, and the second contact pad 710. In some examples, a thickness of one of the first metallic diffusion barrier layers 702 can be at least 0.5 microns.

Turning to FIG. 7B, a second example solder joint (e.g., a second interconnect joint) 714 includes the first contact pad 706 coupled to the via 712, the second contact pad 710, and the solder 708 of FIG. 7A. However, instead of the first metallic diffusion barrier layers 702 of FIG. 7A, the second solder joint 714 includes a first one of the second metallic diffusion barrier layers 704A coupled between the first contact pad 706 and the solder 708, and a second one of the second metallic diffusion barrier layers 704B coupled between the second contact pad 710 and the solder 708. In some examples, one of the second metallic diffusion barrier layers 704 (e.g., the first one of the second metallic diffusion barrier layers 704A or the second one of the second metallic diffusion barrier layers 704B) may be omitted. In some examples, the second metallic diffusion barrier layer 704 can be used for the diffusion barrier layer 214 of FIG. 2 (e.g., in addition to or instead of the organic diffusion barrier layer 500 of FIGS. 5 and/or 6 and/or the first metallic diffusion barrier layer 702 of FIG. 7A).

In the illustrated example of FIG. 7B, the second metallic diffusion barrier layer(s) 704 include a second example alloy (e.g., an iron-cobalt (FeCo) alloy) including iron (Fe) and cobalt (Co). In some examples, the second metallic diffusion barrier layer(s) 704 can be provided on a surface of at least one of the first contact pad 706, the second contact pad 710, or the solder 708 using at least one of an electrolytic plating technique or an electroless plating technique. For example, iron and cobalt can be combined to produce the iron-cobalt alloy, and the iron-cobalt alloy can be provided (e.g., deposited) on the at least one of the first contact pad 706, the second contact pad 710, or the solder 708. In some examples, alternating layers of iron and cobalt are provided on the at least one of the first contact pad 706, the second contact pad 710, or the solder 708, and heat and/or pressure is applied to the layers of iron and cobalt to produce the iron-cobalt alloy. In some examples, thermocompression bonding can be used to couple (e.g., join, combine) together the first contact pad 706, the first one of the second metallic diffusion barrier layers 704A, the solder 708, the second one of the second metallic diffusion barrier layers 704B, and the second contact pad 710. In some examples, a thickness of one of the second metallic diffusion barrier layers 704 is at least 0.5 microns.

FIGS. 8A and 8B illustrate a third example solder joint (e.g., a third interconnect joint) 802 and a fourth example solder joint (e.g., a fourth interconnect joint) 804, respectively, that may be implemented in the example IC package 100 of FIG. 1. In particular, at least one of the third solder joint 802 or the fourth solder joint 804 may be included in the IC package 100 in some examples. In the illustrated example of FIG. 8A, the third solder joint 802 includes the first contact pad 706, the second contact pad 710, and the via 712 of FIGS. 7A and/or 7B, but does not include the first metallic diffusion barrier layers 702 or the second metallic diffusion barrier layers 704. Further, instead of the solder 708 of FIGS. 7A and/or 7B, the third solder joint 802 includes second example solder (e.g., second solder material) 806 coupled between the first and second contact pads 706, 710. In this example, the second solder 806 is a third example alloy including tin and indium. In some examples, the indium is between 0.001 weight percent and 15 weight percent of the second solder 806. In some examples, the second solder 806 can include less than a threshold amount of indium. For example, the second solder 806 can include less than 90 weight percent of indium, less than 80 weight percent of indium, less than 70 weight percent of indium, less than 60 weight percent of indium, less than 50 weight percent of indium, less than 40 weight percent of indium, less than 30 weight percent of indium, less than 20 weight percent of indium, less than 10 weight percent of indium, etc.

In some examples, the tin and indium can be combined to produce the third alloy prior to the third alloy being provided (e.g., deposited) on at least one of the first contact pad 706 or the second contact pad 710. In some examples, alternating layers of tin and indium are provided (e.g., plated) on the at least one of the first contact pad 706 or the second contact pad 710, and heat and/or pressure is applied to the layers of tin and indium (e.g., during thermocompression bonding) to combine (e.g., melt together) the layers to produce the third alloy. In some examples, one or more additional materials (e.g., dopants, trace materials) can be included in the second solder 806. For example, trace amounts (e.g., 0.1 weight percent or above) of at least one of nickel, silver, germanium, etc. can be included in the second solder 806.

Turning to FIG. 8B, the fourth example solder joint 804 includes the first contact pad 706, the second contact pad 710, and the via 712 of FIG. 8A, but does not implement the second solder 806 of FIG. 8A. Instead, the fourth solder joint 804 includes third example solder (e.g., third solder material) 808 electrically and/or mechanically coupled between the first and second contact pads 706, 710. In this example, the third solder 808 is a fourth example alloy including tin, indium, and copper. In some examples, the indium is between 0.001 weight percent and 15 weight percent of the second solder 806. In some examples, the third solder 808 can include less than a threshold amount of indium. For example, the third solder 808 can include less than 90 weight percent of indium, less than 80 weight percent of indium, less than 70 weight percent of indium, less than 60 weight percent of indium, less than 50 weight percent of indium, less than 40 weight percent of indium, less than 30 weight percent of indium, less than 20 weight percent of indium, less than 10 weight percent of indium, etc.

In some examples, the tin, indium, and copper of the third solder 808 can be combined to produce the fourth alloy prior to the fourth alloy being provided (e.g., deposited) on at least one of the first contact pad 706 or the second contact pad 710. In some examples, alternating layers of tin, indium, and copper are provided (e.g., plated) on the at least one of the first contact pad 706 or the second contact pad 710, and heat and/or pressure is applied to the layers of tin, indium, and copper (e.g., during thermocompression bonding) to combine (e.g., melt together) the layers to produce the fourth alloy. In some examples, one or more additional materials (e.g., dopants, trace materials) can be included in the third solder 808. For example, trace amounts (e.g., 0.1 weight percent or above) of at least one of nickel, silver, germanium, etc. can be included in the third solder 808.

In some examples, the second solder 806 and/or the third solder 808 can more effectively inhibit electromigration and/or diffusion of material from the first and second contact pads 706, 710 compared to when the solder 708 of FIGS. 7A and/or 7B (e.g., including tin without (or with only trace amounts of) other materials)) is used. In some examples, at least one of the third solder joint 802 or the fourth solder joint 804 can implement and/or include at least one of the organic diffusion barrier layer 500 of FIGS. 5 and/or 6, the first metallic diffusion barrier layer(s) 702 of FIG. 7A, or the second metallic diffusion barrier layer(s) 704 of FIG. 7B to further reduce and/or inhibit electromigration.

In some examples, a weight percent of nickel in any layer of material between the first and second contact pads 706, 710 is less than a threshold (e.g., 1%, 0.1%, etc.). For example, the weight percent of nickel in any of the organic diffusion barrier layer 500 of FIGS. 5 and/or 6, the first metallic diffusion barrier layer(s) 702 of FIG. 7A, and/or the second metallic diffusion barrier layer(s) 704 of FIG. 7B may be less than the threshold. In some examples, the weight percent of nickel can be less than 90%, less than 80%, less than 70%, less than 60%, less than 50%, less than 40%, less than 30%, less than 20%, less than 10%, less than 5%, less than 1%, less than 0.1%, etc. In some examples, the threshold being less than 100% indicates there is no layer of solid or pure (or substantially pure) nickel (e.g., nickel without (or with only trace amounts) of other materials). For example, there may be no discrete layer of nickel between the first and second contact pads 706, 710.

In some examples, any combination of the organic diffusion barrier layer 500, the first metallic diffusion barrier layer 702, the second metallic diffusion barrier layer 704, the solder 708, the second solder 806, and the third solder 808 may be implemented in the example IC package 100 of FIG. 1. For example, one or more of the organic diffusion barrier layer 500, one or more of the first metallic diffusion barrier layer 702, one or more of the second metallic diffusion barrier layer 704, the solder 708, the second solder 806, and/or the third solder 808 can be used in combination for a same individual joint in the IC package 100. In some examples, different combinations of the organic diffusion barrier layer 500, the first metallic diffusion barrier layer 702, the second metallic diffusion barrier layer 704, the solder 708, the second solder 806, and/or the third solder 808 can be used in different (e.g., separate) joints within the same package 100. In some examples, a first one or more of the organic diffusion barrier layer 500, the first metallic diffusion barrier layer 702, or the second metallic diffusion barrier layer 704 can be used as a first barrier layer on the first contact pad 706, and a second one or more (e.g., the same as or different from the first one or more) of the organic diffusion barrier layer 500, the first metallic diffusion barrier layer 702, or the second metallic diffusion barrier layer 704 can be used as a second barrier layer on the second contact pad 710. In some examples, a combination of the solder 708, the second solder 806, and/or the third solder 808 can be used in a same joint of the IC package 100, and/or different combinations of the solder 708, the second solder 806, and/or the third solder 808 can be used in different (e.g., separate) joints within the same IC package 100.

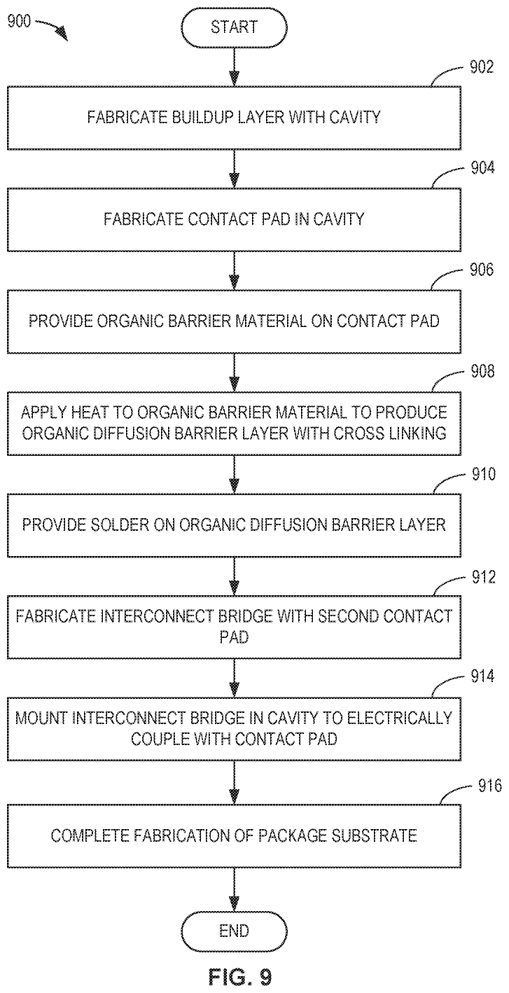

FIG. 9 is a flowchart representative of an example method 900 to manufacture the example package substrate 110 of FIGS. 1 and/or 2 including the example organic diffusion barrier layer 500 of FIGS. 5 and/or 6. In some examples, some or all of the operations outlined in the example method of FIG. 9 are performed automatically by fabrication equipment that is programmed to perform the operations. Although the example method of manufacture is described with reference to the flowchart illustrated in FIG. 9, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 9, the example process begins at block 902 at which the example buildup layer 204 of the package substrate 110 is fabricated with the example cavity 130 of FIGS. 1 and/or 2. For example, the buildup layer 204 is fabricated by providing layers of nonconductive (e.g., dielectric) material on the surface 206 of the example core 202 of FIG. 2. In some examples, the buildup layer 204 is fabricated to include the cavity 130. In some examples, material is removed from the buildup layer 204 to create the cavity 130.

At block 904, the example contact pad 300 of FIG. 3 is fabricated in the cavity 130. For example, the contact pad 300 can correspond to one of the first contact pads 132 positioned in the cavity 130 of FIGS. 1 and/or 2. In some examples, the contact pad 300 is fabricated from a first metallic material (e.g., copper). While the contact pad 300 is described as corresponding to one of the first contact pads 132 in this example, the contact pad 300 can be used for one or more different contact pads in the example IC package 100 and/or the package substrate 110 of FIG. 1. For example, the contact pad 300 may correspond to one of the contact pads on a surface of the interconnect bridge 128 (e.g., one of the second contact pads 134 on the second surface 210 of the interconnect bridge 128 and/or one of the third contact pads 218 on the third surface 220 of the interconnect bridge 128). In some examples, the contact pad 300 corresponds to one of the contact pads on a surface of the package substrate 110 (e.g., one of the contact pads 104 on the bottom surface 105 of the package substrate 110 and/or one of the fourth contact pads 120 on the inner surface 122 of the package substrate 110). In some examples, when the contact pad 300 corresponds to one of the contact pads on a surface of the package substrate 110, the buildup layer 204 is fabricated (e.g., at block 902) without the cavity 130.

At block 906, the example organic barrier material 400 of FIG. 4 is provided on the contact pad 300. For example, the organic barrier material 400 is provided (e.g., deposited) in one or more layers to coat the surface 402 of the contact pad 300. In some examples, the organic barrier material 400 includes an example thermal cross-linker and/or an example photo cross-linker. In some examples, the organic barrier material 400 includes at least one substituent material (e.g., benzimidazole and/or a carboxylic acid).

At block 908, heat is applied to the organic barrier material 400 to produce the example organic diffusion barrier layer 500 with cross-linking. For example, when the heat and/or light is applied to the organic barrier material 400, the cross-linker (e.g., the thermal cross-linker and/or the photo cross-linker) and the at least one substituent material are bonded together to produce the organic diffusion barrier layer 500 with cross-linking. In some examples, a temperature of the heat applied to the organic barrier material 400 is between 200 degrees Celsius and 300 degrees Celsius.

At block 910, example solder is provided on the organic diffusion barrier layer 500. In some examples, the solder corresponds to the solder 600 of FIG. 6 and includes tin. In some examples, the solder corresponds to the second solder 806 of FIG. 8A including tin and indium, and/or corresponds to the third solder 808 of FIG. 8B including tin, indium, and copper. In some examples, the solder is deposited in one or more layers (e.g., alternating layers of tin, indium, and/or copper) on the contact pad 300.

At block 912, the example interconnect bridge 128 is fabricated with one of the second contact pads 134 of FIGS. 1 and/or 2. For example, the second contact pads 132 are positioned on the second surface 210 of the interconnect bridge 128 and are fabricated from the first metallic material. In some examples, the one of the second contact pads 134 includes a diffusion barrier layer (e.g., at least one of a second one of the organic diffusion barrier layer 500, the first metallic diffusion barrier layer(s) 702 of FIG. 7A, or the second metallic diffusion barrier layers 704 of FIG. 7B) positioned thereon. In some examples, when the contact pad 300 corresponds to one of the contact pads on a surface of the package substrate 110 and/or when the buildup layer 204 is fabricated without the cavity 130, block 912 may be omitted.

At block 914, the example interconnect bridge 128 is mounted in the cavity 130 and electrically coupled to the contact pad 300. For example, one of the second contact pads 134 of the interconnect bridge 128 is substantially aligned with the contact pad 300, and the one of the second contact pads 134 is electrically and/or mechanically coupled to the contact pad 300 via the solder. In some examples, the one of the second contact pads 134 is coupled to the contact pad 300 using thermocompression bonding. In some examples, when the contact pad 300 corresponds to one of the contact pads on a surface of the package substrate 110 and/or when the buildup layer 204 is fabricated without the cavity 130, block 914 may be omitted.

At block 916, fabrication of the package substrate 110 is completed. For example, one or more example vias (e.g., the vias 228 of FIG. 2) can be provided in the buildup layer 204. In some examples, the buildup layer 204 can be filled in between the walls 216 of the cavity 130 and the interconnect bridge 128 to complete fabrication of the package substrate 110.

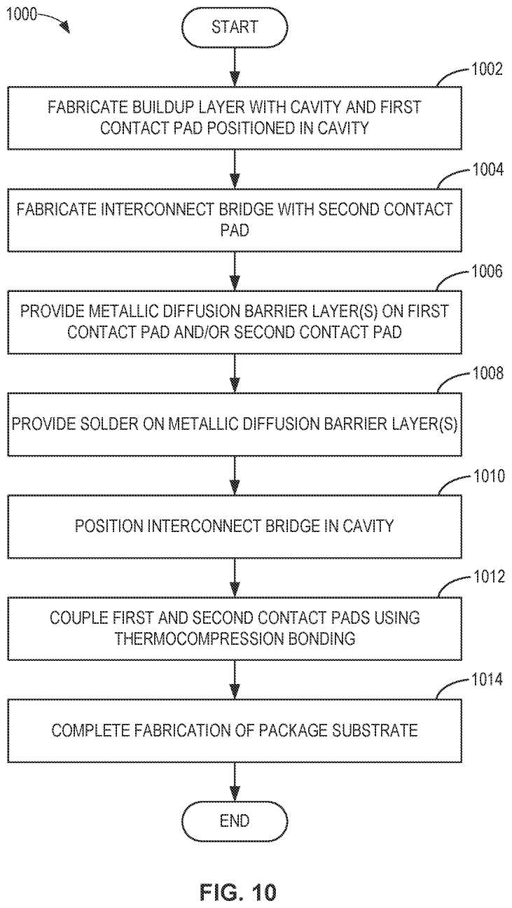

FIG. 10 is a flowchart representative of an example method 1000 to manufacture the example package substrate 110 of FIGS. 1 and/or 2 including an example metallic diffusion barrier layer (e.g., the first example metallic diffusion barrier layer(s) 702 of FIG. 7A and/or the second example metallic diffusion barrier layer(s) 704 of FIG. 7B), the second example solder 806 of FIG. 8A, and/or the third example solder 808 of FIG. 8B. In some examples, some or all of the operations outlined in the example method of FIG. 10 are performed automatically by fabrication equipment that is programmed to perform the operations. Although the example method of manufacture is described with reference to the flowchart illustrated in FIG. 10, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

Turning to FIG. 10, the example process begins at block 1002 at which the example buildup layer 204 of the package substrate 110 is fabricated with the example cavity 130 and one of the first contact pads 132 of FIGS. 1 and/or 2. For example, the buildup layer 204 is fabricated by providing layers of nonconductive (e.g., dielectric) material on the surface 206 of the example core 202 of FIG. 2. In some examples, the buildup layer 204 is fabricated to include the cavity 130. In some examples, material is removed from the buildup layer 204 to create the cavity 130. Further, a first example metallic material (e.g., copper) is provided in the cavity 130 to fabricate the first contact pad 132. While the process 1000 of FIG. 10 is described in connection with one of the first contact pads 132, process 1000 can be applied to one or more different contact pads in the example IC package 100 and/or the package substrate 110 of FIG. 1. For example, the process 1000 may be applied to one of the contact pads on a surface of the interconnect bridge 128 (e.g., one of the second contact pads 134 on the second surface 210 of the interconnect bridge 128 and/or one of the third contact pads 218 on the third surface 220 of the interconnect bridge 128). In some examples, the process 1000 may be applied to one of the contact pads on a surface of the package substrate 110 (e.g., one of the contact pads 104 on the bottom surface 105 of the package substrate 110 and/or one of the fourth contact pads 120 on the inner surface 122 of the package substrate 110). In some examples, when the process 1000 is applied to one of the contact pads on a surface of the package substrate 110, the buildup layer 204 may be fabricated without the cavity 130.

At block 1004, the example interconnect bridge 128 is fabricated with one of the second contact pads 134 of FIGS. 1 and/or 2. For example, the second contact pads 132 are positioned on the second surface 210 of the interconnect bridge 128 and are fabricated from the first metallic material. In some examples, block 1004 may be omitted, and the one of the second contact pads 134 may correspond to a contact pad on a semiconductor die (e.g., one of the dies 106, 108 of FIG. 1).

At block 1006, one or more example metallic diffusion barrier layers are provided on at least one of the first contact pad 132 or the second contact pad 134. For example, one(s) of the first metallic diffusion barrier layers 702 of FIG. 7A can be provided (e.g., plated) on at least one of the first contact pad 132 or the second contact pad 134, where the first metallic diffusion barrier layer(s) 702 include nickel and iron. Additionally or alternatively, one(s) of the second metallic diffusion barrier layers 704 of FIG. 7B can be provided on at least one of the first contact pad 132 or the second contact pad 134, where the second metallic diffusion barrier layer(s) 704 include iron and cobalt.

At block 1008, example solder is provided on at least one of the metallic diffusion barrier layers. In some examples, the solder corresponds to the solder 708 of FIGS. 7A and/or 7B and includes tin. In some examples, the solder corresponds to the second solder 806 of FIG. 8A including tin and indium, and/or corresponds to the third solder 808 of FIG. 8B including tin, indium, and copper. In some examples, the solder is deposited in one or more layers (e.g., alternating layers of tin, indium, and/or copper) on the at least one of the metallic diffusion barrier layers.

At block 1010, the interconnect bridge 128 is positioned in the cavity 130. For example, the interconnect bridge 128 is positioned such that the first contact pad 132 of the buildup layer 204 is substantially aligned with the second contact pad 134 of the interconnect bridge 128.

At block 1012, the first and second contact pads 132, 134 are coupled together using thermocompression bonding. For example, pressure and/or heat is applied to the first and second contact pads 132, 134 to couple together the first and second contact pads 132, 134 with the solder and the metallic diffusion barrier layer(s).

At block 1014, fabrication of the package substrate 110 is completed. For example, one or more example vias (e.g., the vias 228 of FIG. 2) can be provided in the buildup layer 204. In some examples, the buildup layer 204 can be filled in between the walls 216 of the cavity 130 and the interconnect bridge 128 to complete fabrication of the package substrate 110.

The example package substrate 110 including at least one of the organic diffusion barrier layer 500, the first metallic diffusion barrier layer 702, the second metallic diffusion barrier layer 704, the second solder 806, or the third solder 808 disclosed herein may be included in any suitable electronic component. FIGS. 11-14 illustrate various examples of apparatus that may include or be included in the package substrate 110 and/or the associated IC package 100 disclosed herein.

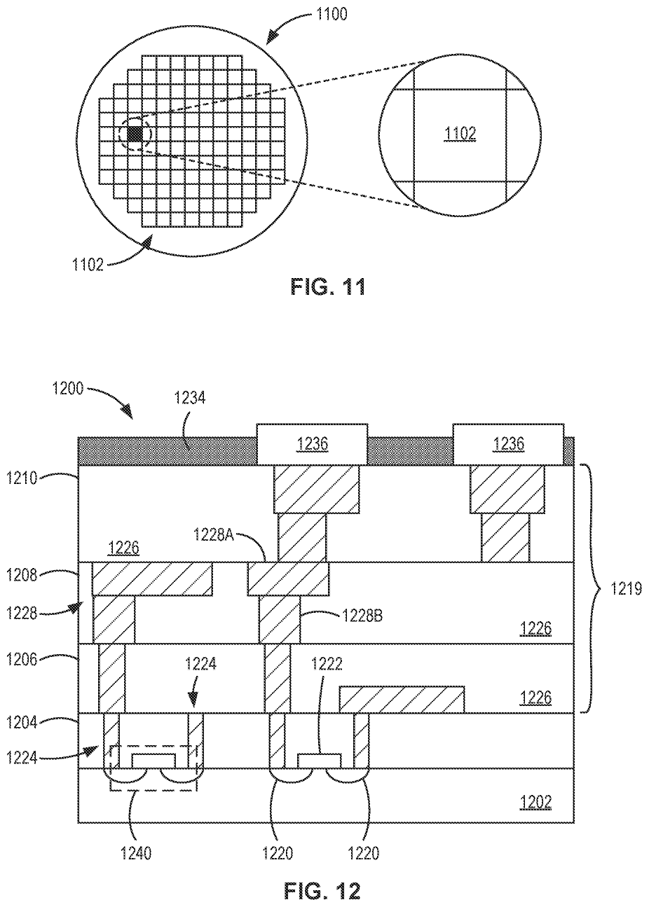

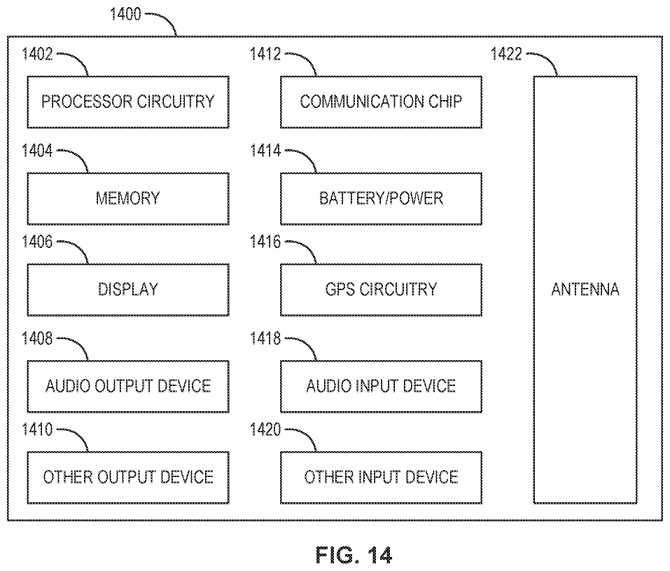

FIG. 11 is a top view of a wafer 1100 and dies 1102 that may be included in the example IC package 100 of FIG. 1 (e.g., as any suitable ones of the dies 106, 108). The wafer 1100 may be composed of semiconductor material and may include one or more dies 1102 having circuitry. Each of the dies 1102 may be a repeating unit of a semiconductor product. After the fabrication of the semiconductor product is complete, the wafer 1100 may undergo a singulation process in which the dies 1102 are separated from one another to provide discrete “chips.” The die 1102 may include one or more transistors (e.g., some of the transistors 1240 of FIG. 12, discussed below), supporting circuitry to route electrical signals to the transistors, passive components (e.g., traces, resistors, capacitors, inductors, and/or other circuitry), and/or any other components. In some examples, the die 1102 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 1102. For example, a memory array formed by multiple memory circuits may be formed on a same die 1102 as programmable circuitry (e.g., the processor circuitry 1402 of FIG. 14) or other logic circuitry. Such memory may store information for use by the programmable circuitry. The example IC package 100 disclosed herein may be manufactured using a die-to-wafer assembly technique in which some dies are attached to a wafer 1100 that include others of the dies, and the wafer 1100 is subsequently singulated.

FIG. 12 is a cross-sectional side view of an IC device 1200 that may be included in the example IC package 100 (e.g., in any one of the dies 106, 108) of FIG. 1. One or more of the IC devices 1200 may be included in one or more dies 1102 (FIG. 11). The IC device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some examples, the die substrate 1202 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an IC device 1200 may be used. The die substrate 1202 may be part of a singulated die (e.g., the dies 1102 of FIG. 11) or a wafer (e.g., the wafer 1100 of FIG. 11).

The IC device 1200 may include one or more device layers 1204 disposed on or above the die substrate 1202. The device layer 1204 may include features of one or more transistors 1240 (e.g., metal oxide semiconductor field-effect transistors (MOSFETs)) formed on the die substrate 1202. The device layer 1204 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other examples, at least one of the metal layers that form the gate electrode may simply be a planar layer that is substantially parallel to the top surface of the die substrate 1202 and does not include sidewall portions substantially perpendicular to the top surface of the die substrate 1202. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of each transistor 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1220 may be formed using one or more alternate semiconductor materials such as germanium or a group III-V material or alloy. In further examples, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the IC device 1200.

The interconnect structures 1228 may be arranged within the interconnect layers 1206-1210 to route electrical signals according to a wide variety of designs (in particular, the arrangement is not limited to the particular configuration of interconnect structures 1228 depicted in FIG. 12). Although a particular number of interconnect layers 1206-1210 is depicted in FIG. 12, examples of the present disclosure include IC devices having more or fewer interconnect layers than depicted.

In some examples, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page from the perspective of FIG. 12. The vias 1228b may be arranged to route electrical signals in a direction of a plane that is substantially perpendicular to the surface of the die substrate 1202 upon which the device layer 1204 is formed. In some examples, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some examples, the dielectric material 1226 disposed between the interconnect structures 1228 in different ones of the interconnect layers 1206-1210 may have different compositions; in other examples, the composition of the dielectric material 1226 between different interconnect layers 1206-1210 may be the same.

A first interconnect layer 1206 (referred to as Metal 1 or “M1”) may be formed directly on the device layer 1204. In some examples, the first interconnect layer 1206 may include lines 1228a and/or vias 1228b, as shown. The lines 1228a of the first interconnect layer 1206 may be coupled with contacts (e.g., the S/D contacts 1224) of the device layer 1204.

A second interconnect layer 1208 (referred to as Metal 2 or “M2”) may be formed directly on the first interconnect layer 1206. In some examples, the second interconnect layer 1208 may include vias 1228b to couple the lines 1228a of the second interconnect layer 1208 with the lines 1228a of the first interconnect layer 1206. Although the lines 1228a and the vias 1228b are structurally delineated with a line within each interconnect layer (e.g., within the second interconnect layer 1208) for the sake of clarity, the lines 1228a and the vias 1228b may be structurally and/or materially contiguous (e.g., simultaneously filled during a dual-damascene process) in some examples.

A third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some examples, the interconnect layers that are “higher up” in the metallization stack 1219 in the IC device 1200 (i.e., further away from the device layer 1204) may be thicker.

The IC device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to other external devices. For example, solder bonds may be formed on the one or more conductive contacts 1236 to mechanically and/or electrically couple a chip including the IC device 1200 with another component (e.g., a circuit board). The IC device 1200 may include additional or alternate structures to route the electrical signals from the interconnect layers 1206-1210; for example, the conductive contacts 1236 may include other analogous features (e.g., posts) that route the electrical signals to external components.

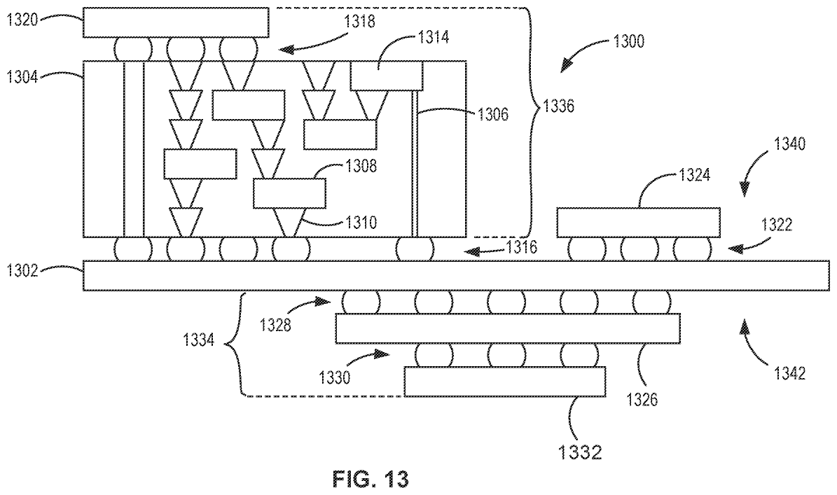

FIG. 13 is a cross-sectional side view of an IC device assembly 1300 that may include the example package substrate 110 and/or the associated IC package 100 disclosed herein. In some examples, the IC device assembly corresponds to the IC package 100 of FIG. 1. The IC device assembly 1300 includes a number of components disposed on a circuit board 1302 (which may be, for example, a motherboard). The IC device assembly 1300 includes components disposed on a first face 1340 of the circuit board 1302 and an opposing second face 1342 of the circuit board 1302; generally, components may be disposed on one or both faces 1340 and 1342. Any of the IC packages discussed below with reference to the IC device assembly 1300 may take the form of the example IC package 100 of FIG. 1.

In some examples, the circuit board 1302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1302. In other examples, the circuit board 1302 may be a non-PCB substrate.

The IC device assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), male and female portions of a socket, an adhesive, an underfill material, and/or any other suitable electrical and/or mechanical coupling structure.

The package-on-interposer structure 1336 may include an IC package 1320 coupled to an interposer 1304 by coupling components 1318. The coupling components 1318 may take any suitable form for the application, such as the forms discussed above with reference to the coupling components 1316. Although a single IC package 1320 is shown in FIG. 13, multiple IC packages may be coupled to the interposer 1304; indeed, additional interposers may be coupled to the interposer 1304. The interposer 1304 may provide an intervening substrate used to bridge the circuit board 1302 and the IC package 1320. The IC package 1320 may be or include, for example, a die (the die 1102 of FIG. 11), an IC device (e.g., the IC device 1200 of FIG. 12), or any other suitable component. Generally, the interposer 1304 may spread a connection to a wider pitch or reroute a connection to a different connection. For example, the interposer 1304 may couple the IC package 1320 (e.g., a die) to a set of BGA conductive contacts of the coupling components 1316 for coupling to the circuit board 1302. In the example illustrated in FIG. 13, the IC package 1320 and the circuit board 1302 are attached to opposing sides of the interposer 1304; in other examples, the IC package 1320 and the circuit board 1302 may be attached to a same side of the interposer 1304. In some examples, three or more components may be interconnected by way of the interposer 1304.

In some examples, the interposer 1304 may be formed as a PCB, including multiple metal layers separated from one another by layers of dielectric material and interconnected by electrically conductive vias. In some examples, the interposer 1304 may be formed of an epoxy resin, a fiberglass-reinforced epoxy resin, an epoxy resin with inorganic fillers, a ceramic material, or a polymer material such as polyimide. In some examples, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through-silicon vias (TSVs) 1306. The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The IC device assembly 1300 may include an IC package 1324 coupled to the first face 1340 of the circuit board 1302 by coupling components 1322. The coupling components 1322 may take the form of any of the examples discussed above with reference to the coupling components 1316, and the IC package 1324 may take the form of any of the examples discussed above with reference to the IC package 1320.

The IC device assembly 1300 illustrated in FIG. 13 includes a package-on-package structure 1334 coupled to the second face 1342 of the circuit board 1302 by coupling components 1328. The package-on-package structure 1334 may include a first IC package 1326 and a second IC package 1332 coupled together by coupling components 1330 such that the first IC package 1326 is disposed between the circuit board 1302 and the second IC package 1332. The coupling components 1328, 1330 may take the form of any of the examples of the coupling components 1316 discussed above, and the IC packages 1326, 1332 may take the form of any of the examples of the IC package 1320 discussed above. The package-on-package structure 1334 may be configured in accordance with any of the package-on-package structures known in the art.

FIG. 14 is a block diagram of an example electrical device 1400 that may include one or more of the example package substrate 110 and/or the associated IC package 100. For example, any suitable ones of the components of the electrical device 1400 may include one or more of the device assemblies 1300, IC devices 1200, or dies 1102 disclosed herein, and may be arranged in the example package substrate 110. A number of components are illustrated in FIG. 14 as included in the electrical device 1400, but any one or more of these components may be omitted or duplicated, as suitable for the application. In some examples, some or all of the components included in the electrical device 1400 may be attached to one or more motherboards. In some examples, some or all of these components are fabricated onto a single system-on-a-chip (SoC) die.

Additionally, in various examples, the electrical device 1400 may not include one or more of the components illustrated in FIG. 14, but the electrical device 1400 may include interface circuitry for coupling to the one or more components. For example, the electrical device 1400 may not include a display 1406, but may include display interface circuitry (e.g., a connector and driver circuitry) to which a display 1406 may be coupled. In another set of examples, the electrical device 1400 may not include an audio input device 1418 (e.g., microphone) or an audio output device 1408 (e.g., a speaker, a headset, earbuds, etc.), but may include audio input or output device interface circuitry (e.g., connectors and supporting circuitry) to which an audio input device 1418 or audio output device 1408 may be coupled.

The electrical device 1400 may include programmable circuitry 1402 (e.g., one or more processing devices). The programmable circuitry 1402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1400 may include a memory 1404, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1404 may include memory that shares a die with the programmable circuitry 1402. This memory may be used as cache memory and may include embedded dynamic random access memory (eDRAM) or spin transfer torque magnetic random access memory (STT-MRAM).

In some examples, the electrical device 1400 may include a communication chip 1412 (e.g., one or more communication chips). For example, the communication chip 1412 may be configured for managing wireless communications for the transfer of data to and from the electrical device 1400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1412 may operate in accordance with other wireless protocols in other examples. The electrical device 1400 may include an antenna 1422 to facilitate wireless communications and/or to receive other wireless communications (such as AM or FM radio transmissions).

In some examples, the communication chip 1412 may manage wired communications, such as electrical, optical, or any other suitable communication protocols (e.g., the Ethernet). As noted above, the communication chip 1412 may include multiple communication chips. For instance, a first communication chip 1412 may be dedicated to shorter-range wireless communications such as Wi-Fi or Bluetooth, and a second communication chip 1412 may be dedicated to longer-range wireless communications such as global positioning system (GPS), EDGE, GPRS, CDMA, WiMAX, LTE, EV-DO, or others. In some examples, a first communication chip 1412 may be dedicated to wireless communications, and a second communication chip 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display 1406 (or corresponding interface circuitry, as discussed above). The display 1406 may include any visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any device that generates an audible indicator, such as speakers, headsets, or earbuds.

The electrical device 1400 may include an audio input device 1418 (or corresponding interface circuitry, as discussed above). The audio input device 1418 may include any device that generates a signal representative of a sound, such as microphones, microphone arrays, or digital instruments (e.g., instruments having a musical instrument digital interface (MIDI) output).

The electrical device 1400 may include GPS circuitry 1416. The GPS circuitry 1416 may be in communication with a satellite-based system and may receive a location of the electrical device 1400, as known in the art.

The electrical device 1400 may include any other output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include any other input device 1420 (or corresponding interface circuitry, as discussed above). Examples of the other input device 1420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1400 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that reduce intermetallic compound (IMC) formation in integrated circuit (IC) packages. Examples disclosed herein provide one or more example diffusion barrier layers (e.g., organic diffusion barrier layers and/or metallic diffusion barrier layers) at an interface between an example contact pad and example solder included in the IC package, where the diffusion barrier layer(s) can inhibit diffusion (e.g., electromigration) of material between the contact pad and the solder. Additionally or alternatively, examples disclosed herein utilize metallic alloys (e.g., including tin, indium, and/or copper) for the solder, where such metallic alloys can further reduce and/or inhibit the diffusion therethrough. By reducing the diffusion of material between the contact pad and the solder, examples disclosed herein may reduce IMC formation at an interface between the contact pad and the solder while enabling flow of current therebetween. Accordingly, disclosed systems, apparatus, articles of manufacture, and methods improve the efficiency of using a computing device by improving reliability of mechanical and electrical coupling between semiconductor dies (e.g., interconnect bridges) and package substrates. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to reduce IMC formation in integrated circuit packages are disclosed herein. Further examples and combinations thereof include the following:

Example 1 includes an integrated circuit (IC) package substrate comprising a buildup layer including a metal pad, an interconnect bridge embedded in the buildup layer, the interconnect bridge including a first contact pad on a first side of the interconnect bridge and a second contact pad on a second side of the interconnect bridge, the second side opposite the first side, and solder positioned between the metal pad and the first contact pad, the solder to electrically couple the metal pad and the first contact pad, a weight percent of nickel in any layer of material between the metal pad and the first contact pad being less than a threshold.

Example 2 includes the IC package substrate of example 1, wherein the metal pad and the first contact pad include copper.

Example 3 includes the IC package substrate of example 1, wherein the solder includes at least one of silver, copper, or indium.

Example 4 includes the IC package substrate of example 1, further including a diffusion barrier layer between at least one of (a) the metal pad and the solder or (b) the first contact pad and the solder.

Example 5 includes the IC package substrate of example 4, wherein the diffusion barrier layer includes an organic thermal cross-linked material.

Example 6 includes the IC package substrate of example 5, wherein a thickness of the diffusion barrier layer is between 100 nanometers and 200 nanometers.

Example 7 includes the IC package substrate of example 5, wherein the organic thermal cross-linked material includes at least one of a thermal cross-linker or a photo cross-linker.

Example 8 includes the IC package substrate of example 7, wherein the organic thermal cross-linked material includes at least one of benzimidazole or a carboxylic acid.

Example 9 includes the IC package substrate of example 4, wherein the diffusion barrier layer includes iron and at least one of nickel or cobalt.

Example 10 includes the IC package substrate of example 4, wherein the diffusion barrier layer is to inhibit intermetallic compound formation between the solder and at least one of the metal pad or the first contact pad.

Example 11 includes an integrated circuit (IC) package substrate comprising a recessed surface, a first contact pad positioned on the recessed surface, a semiconductor die including a second contact pad on a first side of the semiconductor die, the first side facing the recessed surface, and a metal interconnect to electrically couple the first contact pad to the second contact pad, the first and second contact pads including copper, the metal interconnect including tin and indium.

Example 12 includes the IC package substrate of example 11, wherein the indium is between example 0 includes 001 weight percent and 15 weight percent of the metal interconnect.

Example 13 includes the IC package substrate of example 11, further including a diffusion barrier layer between at least one of (a) the first contact pad and the metal interconnect or (b) the second contact pad and the metal interconnect.

Example 14 includes the IC package substrate of example 13, wherein the diffusion barrier layer includes an organic material, the organic material including at least one of a thermal cross-linker or a photo cross-linker.

Example 15 includes the IC package substrate of example 13, wherein the diffusion barrier layer includes iron and at least one of nickel or cobalt.

Example 16 includes a method to manufacture an integrated circuit (IC) package, the method comprising fabricating a buildup layer including a first contact pad, mounting an interconnect bridge in the buildup layer, the interconnect bridge including a second contact pad on a first side of the interconnect bridge and a third contact pad on a second side of the interconnect bridge, the second side opposite the first side, and positioning solder between the first contact pad and the second contact pad, the solder to electrically couple the first contact pad and the second contact pad, wherein there is no discrete layer of nickel between the first contact pad and the second contact pad.

Example 17 includes the method of example 16, further including providing a diffusion barrier layer between at least one of (a) the first contact pad and the solder or (b) the second contact pad and the solder.

Example 18 includes the method of example 17, wherein the diffusion barrier layer includes an organic material, the organic material including at least one of a thermal cross-linker or a photo cross-linker.

Example 19 includes the method of example 18, further including applying heat to the diffusion barrier layer to facilitate cross-linking of the organic material, a temperature of the heat being between 200 degrees Celsius and 300 degrees Celsius.

Example 20 includes the method of example 17, wherein the providing of the diffusion barrier layer includes providing an alloy on at least one of the first contact pad or the second contact pad, the alloy including iron and at least one of nickel or cobalt.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit (IC) package substrate comprising:
a buildup layer including a metal pad;
an interconnect bridge embedded in the buildup layer, the interconnect bridge including a first contact pad on a first side of the interconnect bridge and a second contact pad on a second side of the interconnect bridge, the second side opposite the first side; and
solder positioned between the metal pad and the first contact pad, the solder to electrically couple the metal pad and the first contact pad, a weight percent of nickel in any layer of material between the metal pad and the first contact pad being less than a threshold.

2. The IC package substrate of claim 1, wherein the metal pad and the first contact pad include copper.

3. The IC package substrate of claim 1, wherein the solder includes at least one of silver, copper, or indium.

4. The IC package substrate of claim 1, further including a diffusion barrier layer between at least one of (a) the metal pad and the solder or (b) the first contact pad and the solder.

5. The IC package substrate of claim 4, wherein the diffusion barrier layer includes an organic thermal cross-linked material.

6. The IC package substrate of claim 5, wherein a thickness of the diffusion barrier layer is between 100 nanometers and 200 nanometers.

7. The IC package substrate of claim 5, wherein the organic thermal cross-linked material includes at least one of a thermal cross-linker or a photo cross-linker.

8. The IC package substrate of claim 7, wherein the organic thermal cross-linked material includes at least one of benzimidazole or a carboxylic acid.

9. The IC package substrate of claim 4, wherein the diffusion barrier layer includes iron and at least one of nickel or cobalt.

10. The IC package substrate of claim 4, wherein the diffusion barrier layer is to inhibit intermetallic compound formation between the solder and at least one of the metal pad or the first contact pad.

11. An integrated circuit (IC) package substrate comprising:
a recessed surface;
a first contact pad positioned on the recessed surface;
a semiconductor die including a second contact pad on a first side of the semiconductor die, the first side facing the recessed surface; and
a metal interconnect to electrically couple the first contact pad to the second contact pad, the first and second contact pads including copper, the metal interconnect including tin and indium.

12. The IC package substrate of claim 11, wherein the indium is between 0.001 weight percent and 15 weight percent of the metal interconnect.

13. The IC package substrate of claim 11, further including a diffusion barrier layer between at least one of (a) the first contact pad and the metal interconnect or (b) the second contact pad and the metal interconnect.

14. The IC package substrate of claim 13, wherein the diffusion barrier layer includes an organic material, the organic material including at least one of a thermal cross-linker or a photo cross-linker.

15. The IC package substrate of claim 13, wherein the diffusion barrier layer includes iron and at least one of nickel or cobalt.

16. A method to manufacture an integrated circuit (IC) package, the method comprising:
fabricating a buildup layer including a first contact pad;
mounting an interconnect bridge in the buildup layer, the interconnect bridge including a second contact pad on a first side of the interconnect bridge and a third contact pad on a second side of the interconnect bridge, the second side opposite the first side; and
positioning solder between the first contact pad and the second contact pad, the solder to electrically couple the first contact pad and the second contact pad, wherein there is no discrete layer of nickel between the first contact pad and the second contact pad.

17. The method of claim 16, further including providing a diffusion barrier layer between at least one of (a) the first contact pad and the solder or (b) the second contact pad and the solder.

18. The method of claim 17, wherein the diffusion barrier layer includes an organic material, the organic material including at least one of a thermal cross-linker or a photo cross-linker.

19. The method of claim 18, further including applying heat to the diffusion barrier layer to facilitate cross-linking of the organic material, a temperature of the heat being between 200 degrees Celsius and 300 degrees Celsius.

20. The method of claim 17, wherein the providing of the diffusion barrier layer includes providing an alloy on at least one of the first contact pad or the second contact pad, the alloy including iron and at least one of nickel or cobalt.
